(19) United States
(12) Patent Application Publication
(10) Pub. No.: US 2026/0082655 A1
(43) Pub. Date: Mar. 19, 2026

(54) SEMICONDUCTOR DEVICES HAVING CONTACT FIELD PLATE AND METHODS

(71) Applicant: Taiwan Semiconductor Manufacturing Company, Ltd., Hsinchu (TW)

(72) Inventors: Bo-Chang Lai, New Taipei (TW); Cheng-Wei Wu, Taichung (TW); Li-Hsin Chu, New Taipei (TW); Wen-Chih Chiang, Hsinchu (TW)

(21) Appl. No.: 18/888,951

(22) Filed: Sep. 18, 2024

(51) Int. Cl. H01L 29/40; H01L 21/768; H01L 23/522

(52) U.S. Cl. CPC H10D 64/112; H10W 20/056; H10W 20/075; H10W 20/42

(57) ABSTRACT

Semiconductor devices are disclosed that include multiple field plate structures along an axis between the gate electrode and the drain electrode. One field plate structure is closer to the gate electrode, and the other field plate structure is closer to the drain electrode. Methods of making such structures use one or more etch stop layers that permit depth control for each field plate structure to provide desired properties.

### BACKGROUND

Integrated circuits are formed on a semiconductor wafer. Photolithographic patterning processes use ultraviolet light to transfer a desired mask pattern to a photoresist on a semiconductor wafer. Etching processes may then be used to transfer to the pattern to a layer below the photoresist. This process is repeated multiple times with different patterns to build different conductive, resistive, and/or insulating layers on the wafer substrate and make a useful semiconductor device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a cross-sectional view of a first embodiment of a semiconductor device, in accordance with some embodiments of the present disclosure.

FIG. 1B is a magnified view of the first dielectric layer containing two etch stop regions indicated by the dashed-line box in FIG. 1A.

FIG. 1C is one potential plan view of the semiconductor device.

FIG. 1D is another potential plan view of the semiconductor device.

FIG. 1E is a cross-sectional view of a second embodiment of the semiconductor device of FIG. 1A.

FIG. 1F is a cross-sectional view of a third embodiment of the semiconductor device of FIG. 1A.

FIG. 1G is a cross-sectional view of a fourth embodiment of the semiconductor device of FIG. 1A.

FIG. 1H is a cross-sectional view of a fifth embodiment of the semiconductor device of FIG. 1A, including a magnified view of hemispherical electrode ends.

FIG. 1I is a cross-sectional view of a sixth embodiment of the semiconductor device of FIG. 1A.

FIG. 2A is a cross-sectional view of an embodiment of another semiconductor device, in accordance with some embodiments of the present disclosure.

FIG. 2B is a plan view of the metal field plate in the embodiment of FIG. 2A.

FIG. 2C is a magnified cross-sectional view of the electrode ends of the embodiment of FIG. 2A.

FIG. 3A and FIG. 3B together form a flow chart illustrating a first method for forming a semiconductor device, in accordance with some embodiments.

FIG. 4 is an illustrative side view of the substrate after deposition of a gate electrode.

FIG. 5 is an illustrative side view of the substrate after deposition of a photoresist layer for forming a doped well in the substrate.

FIG. 6 is an illustrative side view of the substrate after additional etching of the gate electrode to account for process variation, and doping of the substrate to form the doped well.

FIG. 7 is an illustrative side view of the substrate after formation of dielectric spacer(s) and source/drain electrodes.

FIG. 8 is an illustrative side view of the substrate after deposition of a first dielectric sublayer and a first etch stop layer.

FIG. 9 is an illustrative side view of the substrate after patterning of the first etch stop layer to form a first etch stop region.

FIG. 10 is an illustrative side view of the substrate after deposition of a second dielectric sublayer and a second etch stop layer.

FIG. 11 is an illustrative side view of the substrate after patterning of the second etch stop layer to form a second etch stop region.

FIG. 12 is an illustrative side view of the substrate after deposition of a third dielectric sublayer to obtain a first dielectric layer.

FIG. 13 is an illustrative side view of the substrate after patterning of the first dielectric layer.

FIG. 14 is an illustrative side view of the substrate after deposition of a third etch stop layer.

FIG. 15 is an illustrative side view of the substrate after deposition of an interlayer dielectric (ILD) layer over the substrate and formation of a gate via and a gate pad.

FIG. 16 is an illustrative side view of the substrate after etching through the ILD layer and the third etch stop layer to form openings.

FIG. 17 is an illustrative side view of the substrate after etching through the first dielectric layer to reach the first and second etch stop regions.

FIG. 18 is an illustrative side view of the substrate after etching through the first and second etch stop regions.

FIG. 19 is a flow chart illustrating a method for using a semiconductor device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Numerical values in the specification and claims of this application should be understood to include numerical values which are the same when reduced to the same number of significant figures and numerical values which differ from the stated value by less than the experimental error of conventional measurement technique of the type described in the present application to determine the value. All ranges disclosed herein are inclusive of the recited endpoint.

The term “about” can be used to include any numerical value that can vary without changing the basic function of that value. When used with a range, “about” also discloses the range defined by the absolute values of the two endpoints, e.g. “about 2 to about 4” also discloses the range “from 2 to 4.” The term “about” may refer to plus or minus 10% of the indicated number.

The present disclosure relates to structures which are made up of different layers. When the terms “on” or “upon” or “over” are used with reference to two different layers (including the substrate), they indicate merely that one layer is on, upon, or over the other layer. These terms do not require the two layers to directly contact each other, and permit other layers to be between the two layers. For example, all layers of the structure can be considered to be “on” the substrate, even though they do not all directly contact the substrate. The term “directly” may be used to indicate two layers directly contact each other without any layers in between them. In addition, when referring to performing process steps to the substrate or upon the substrate, this should be construed as performing such steps to whatever layers may be present on the substrate as well, depending on the context.

The present disclosure relates to semiconductor devices with improved properties and processes for making and using such devices. In high voltage devices, for example between 16 volts and 24 volts, hot carrier induced (HCl) degradation can occur as carriers become trapped in the oxide. These trapped charges cause time dependent shifts in measured device parameters such as the linear drain current (I_{DLIN}). This can reduce the power efficiency of buck converters which decrease voltage while increasing current.

Semiconductor devices like transistors can be constructed to have field plates. Field plates are conductive elements which are placed over a portion of the device, such as a channel region, to enhance the performance of the device by inducing electric fields. For example, the drain-source on-resistance (RDSₒₙ) can be lowered. However, the presence of field plates may also cause the off-state breakdown voltage (BV_{off}) to be undesirably lowered, due to the influence of the electric field on the drain side and along the edge of the gate dielectric layer.

The present disclosure provides semiconductor devices with improved contact field plates (CFPs). The CFPs can have any shape in the length direction, providing tunable horizontal control of the electric field(s). The CFPs can be located at different heights or depths, providing tunable vertical control of the electric field(s). This reduces IDLIN degradation, improves the BV_{off}, and reduces HCl degradation, permitting tuning of these properties.

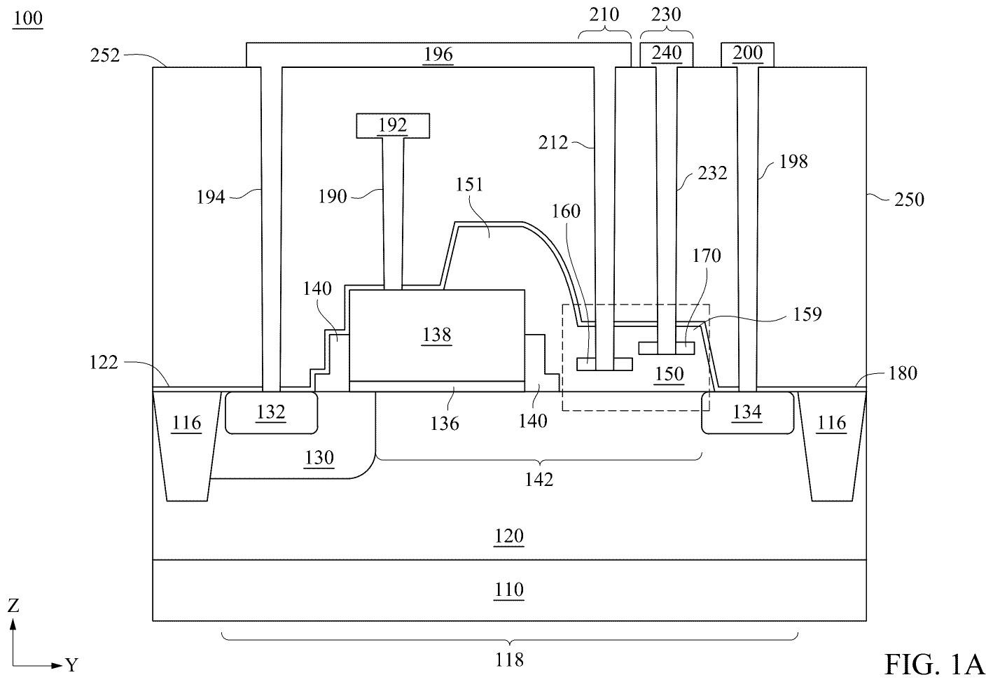

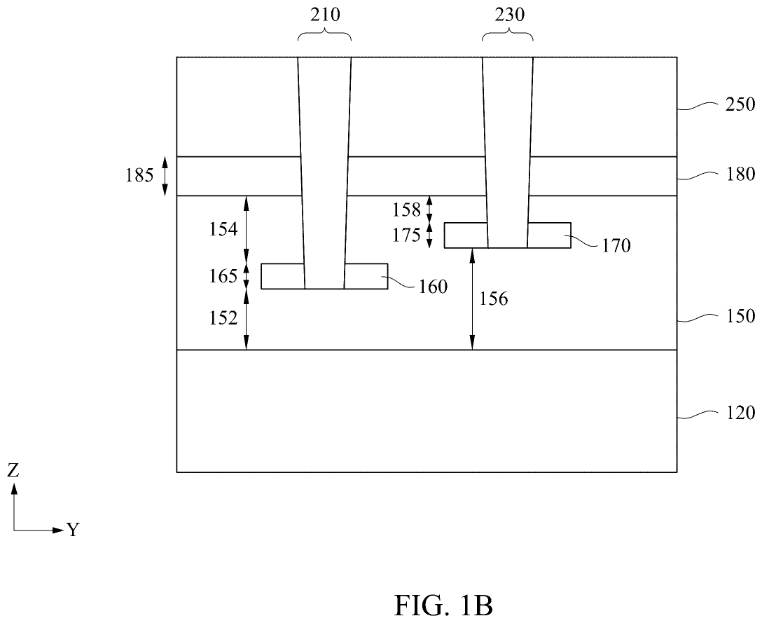

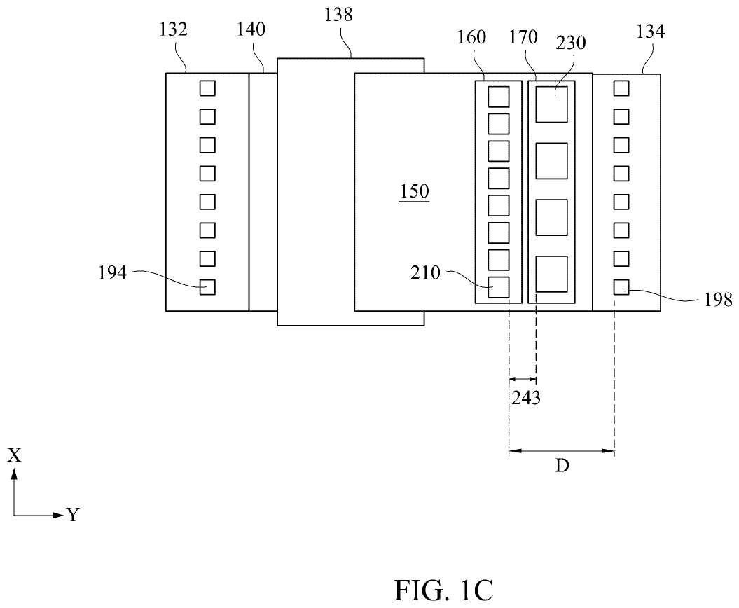

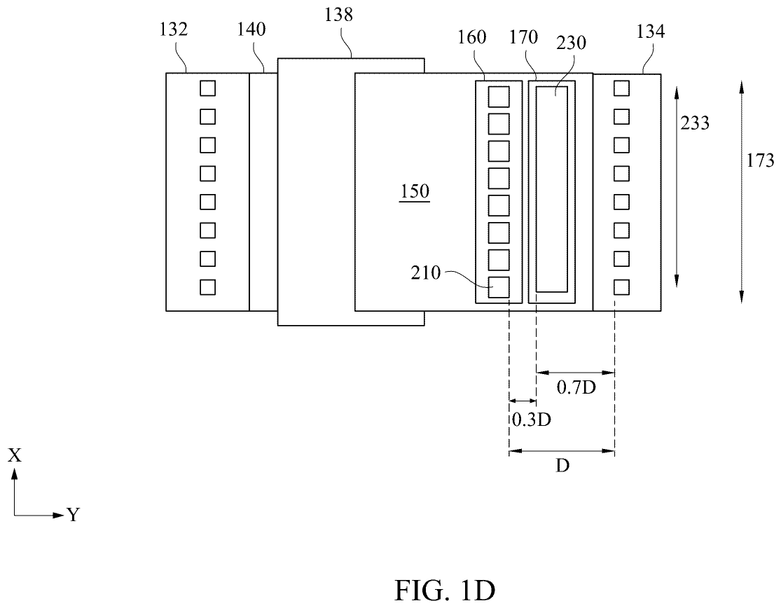

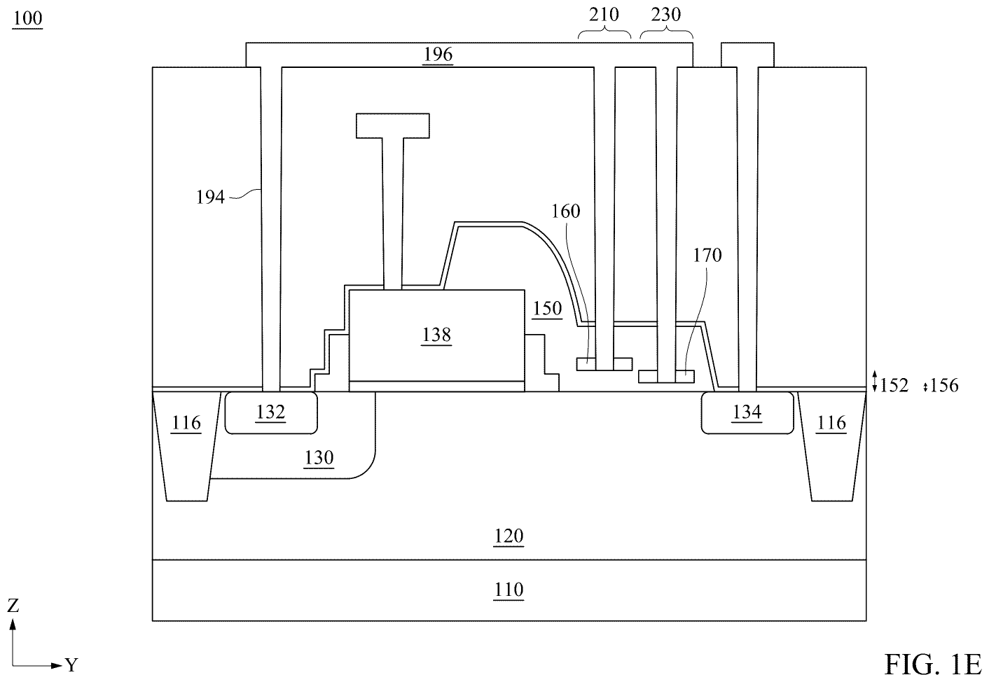

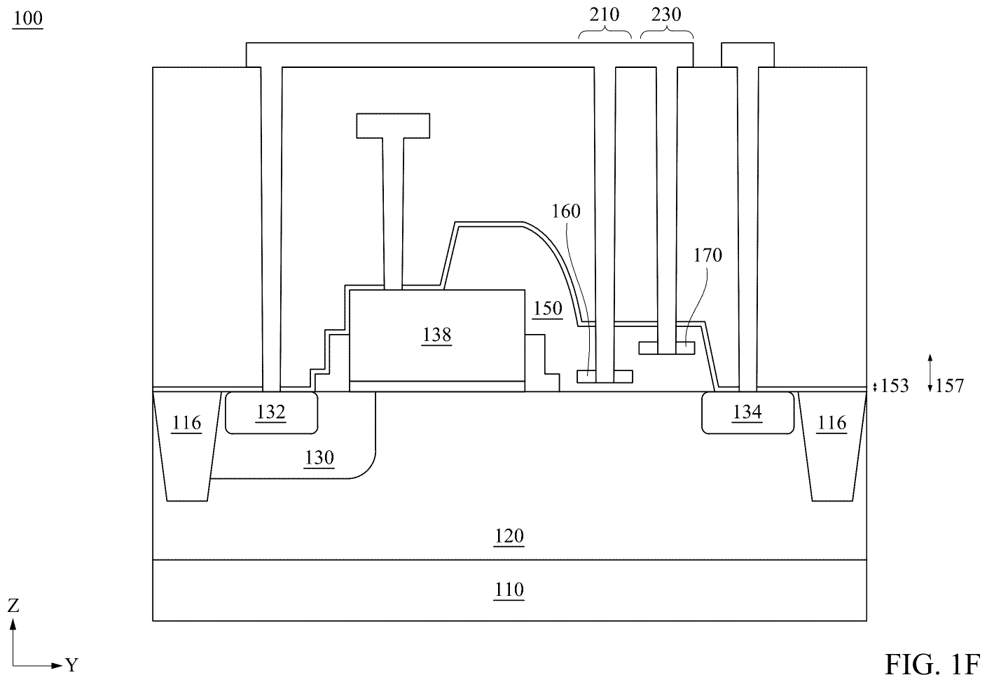

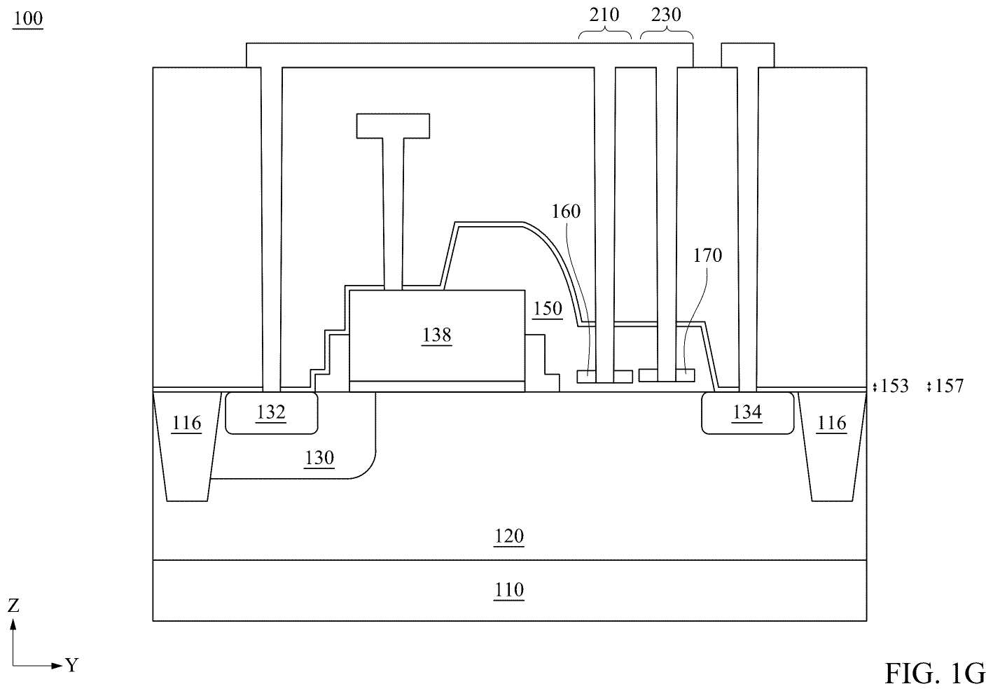

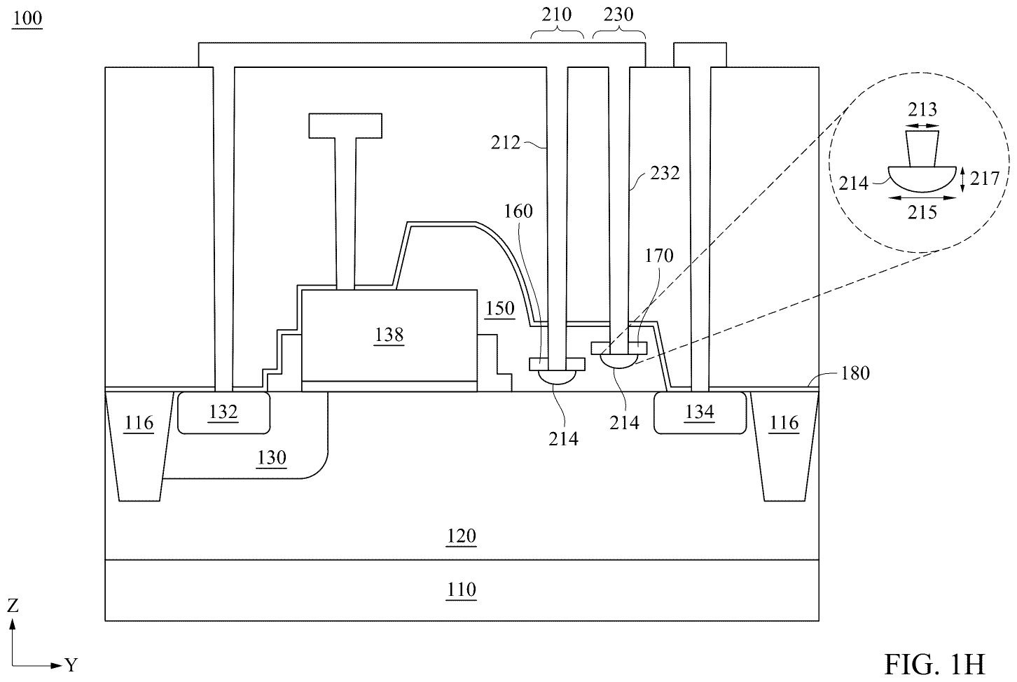

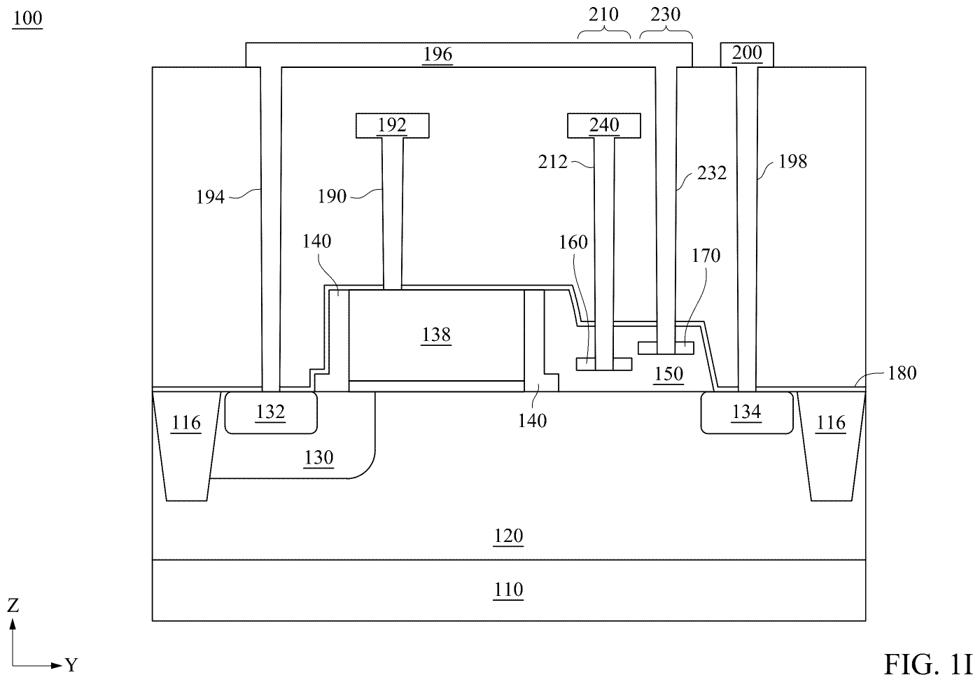

FIG. 1A is a Y-axis cross-sectional view of a semiconductor device 100, in accordance with some embodiments of the present disclosure. The semiconductor device may be, for example, a laterally-diffused metal oxide semiconductor (LDMOS). The semiconductor device 100 is formed within and on a substrate 110. A well 120 of a first dopant type is formed on the substrate 110. Two isolation regions 116 are illustrated as being present on opposite sides of the substrate 110 in the well, and form an active region 118 in between. However, it is noted that these two isolation regions may be connected to each other at other points on the substrate.

As illustrated here, a junction 130 of a second dopant type is present within the well 120 of the first dopant type, on one side of the active region 118. Source/drain (S/D) electrodes 132, 134 are also present on opposite sides of the active region, and are formed from the first dopant type. The source electrode 132 is present within the junction 130 of the second dopant type.

The first dopant type and the second dopant type are of opposite charge. For example, if the first dopant type is an n-type dopant, then the second dopant type is a p-type dopant, and vice versa. In this illustration, the substrate 110 is a p-type substrate, the well 120 is an n-well, the junction 130 is a p-body junction, and the source/drain electrodes 132, 134 are n+ electrodes. In particular embodiments, the first dopant type is an n-type dopant, and the second dopant type is a p-type dopant. Common n-type dopants for silicon substrates may include nitrogen (N), phosphorus (P), arsenic (As), bismuth (Bi), or tantalum (Ta). Common p-type dopants for silicon substrates may include boron (B), aluminum (Al), gallium (Ga), or indium (In).

Continuing, a gate dielectric layer 136 is shown on the well 120, and a gate electrode 138 is located on and contacts the gate dielectric layer 136. At least one gate spacer 140 surrounds the gate dielectric layer 136 and the gate electrode 138. A channel 142 is defined passing through the well, between the junction 130 and the drain electrode 134.

A first dielectric layer 150 is present between the gate electrode 138 and the drain electrode 134, or in other words over the channel 142. Located within the first dielectric layer 150 are a first etch stop region 160 and a second etch stop region 170, which are illustrated here at different heights/depths (depending on point of view). For purposes of the present disclosure, the first etch stop region 160 will be closer to the gate electrode 138 than the second etch stop region 170, regardless of the order in which the two etch stop regions are formed. Put another way, the second etch stop region 170 will be closer to the drain electrode 134 than the first etch stop region 160. As illustrated in this particular embodiment, the first etch stop region 160 is lower (i.e. closer to the upper surface 122 of the n-well) than the second etch stop region 170.

As illustrated here, a hump portion 151 of the first dielectric layer 150 also covers a portion of the gate electrode 138. This is because the device normally operates at a high voltage on the drain side, and this protects the gate spacer 140 from potential damage that might occur during the manufacturing process. However, this is not required.

An etch stop layer 180 is present over and contacts the upper surface 159 of the first dielectric layer 150. The etch stop layer 180 is also present over the gate electrode 138, and the source/drain electrodes 132, 134, and the two isolation regions 116.

One or more gate vias 190 pass through the etch stop layer 180 and electrically contacts the gate electrode 138. A gate pad 192 is present on the gate vias 190. Similarly, source/drain vias 194, 198 pass through the etch stop layer 180 and electrically contact the source electrode 132 and the drain electrode 134. A drain pad 200 is present on the drain vias 198.

A first field plate structure 210 is illustrated here as a first via 212 that passes through the etch stop layer 180 and the first etch stop region 160, and extends into the first dielectric layer 150. A second field plate structure 230 is illustrated here as a second via 232 that passes through the etch stop layer 180 and the second first etch stop region 160, and also extends into the first dielectric layer 150. The various vias 190, 194, 198, 212, 232 also extend through an interlayer dielectric (ILD) layer 250.

In FIG. 1A, the source electrode 132 is electrically connected to the first field plate structure 210 by the source via 194 and a horizontal pad 196. The second field plate structure 230 is connected to a second pad 240. The horizontal pad 196, the gate pad 192, and the drain pad 200 are electrically separated from each other, for example at different heights and/or different locations at the same height. As illustrated here, the gate pad 192 is located within the ILD layer 250. The horizontal pad 196, the drain pad 200, and the second pad 240 are located on the upper surface 252 of the ILD layer 250.

Referring now to FIG. 1B, some additional details are shown. Portions of the well 120 of the first dopant type, the first dielectric layer 150 containing the first etch stop region 160 and the second etch stop region 170, the etch stop layer 180, the first field plate structure 210, the second field plate structure 230, and the ILD layer 250 are illustrated.

A portion of the first dielectric layer is present below the first etch stop region 160, and a portion of the first dielectric layer is present above the first etch stop region 160. The thickness or height of the portion below the first etch stop region is indicated with reference numeral 152. The thickness or height of the portion above the first etch stop region is indicated with reference numeral 154. The sum of these two heights 152, 154 is indicated with the value X.

A portion of the first dielectric layer is present below the second etch stop region 170, and a portion of the first dielectric layer is present above the second etch stop region 170. The thickness or height of the portion below the second etch stop region is indicated with reference numeral 156. The thickness or height of the portion above the second etch stop region is indicated with reference numeral 158. The sum of these two heights 156, 158 will also have the same value X. In particular embodiments, the value of X may be from about 800 angstroms to about 1000 angstroms.

In particular embodiments, the height 185 of the etch stop layer 180 is from about 0.4X to about 0.8X. In particular embodiments, the height 152, 156 of the portions of the first dielectric layer below each etch stop region may independently range from about 0.1X to about 0.9X, including from about 0.2X to about 0.8X, or from about 0.5X to about 0.8X. However, other ranges and values are within the scope of the present disclosure. As illustrated here, the height 152 below the first etch stop region is about 0.5X, the height 156 below the second etch stop region is about 0.8X, and the height 185 of the etch stop layer 180 is about 0.6X.

The thickness or height of the first etch stop region is indicated with reference numeral 165. The thickness or height of the second etch stop region is indicated with reference numeral 175. In particular embodiments, these thicknesses 165, 175 of each etch stop region may independently range from about 0.1X to about 0.3X. If they are too thin, then their etch stop ability may be insufficient. If they are too thick, then they may create too much stress in the first dielectric layer 150.

Referring now to FIG. 1C, the relative locations of the source electrode 132, the gate electrode 138, the first dielectric layer 150 containing the first etch stop region 160 and the second etch stop region 170, and the drain electrode 134 are shown.

Multiple source vias 194 and multiple drain vias 198 are illustrated extending along the X-axis. Multiple first vias 212 extending along the X-axis are also shown. Each individual first via 212 can be considered a first field plate structure 210, or the combination of first vias 212 together can be considered a first field plate structure 210. All of the first vias 212 are usually electrically connected to the same horizontal pad (not shown).

Similarly, multiple second vias 232 extending along the X-axis are shown. Each individual second via 232 can be considered a second field plate structure 230, or the combination of second vias 232 together can be considered a second field plate structure 230. All of the second vias 232 are usually electrically connected to the same second horizontal pad (not shown).

In FIG. 1C, eight square-shaped first field plate structures 210 are illustrated in the first etch stop region 160. Four square-shaped second field plate structures 230 are illustrated in the second etch stop region 170. The number of first field plate structures and second field plate structures are independent of each other, as is their size and/or shape. The shape of each individual first field plate structure is also independent of the other first field plate structures, as is the shape of each individual second field plate structure respectively. Similarly, the length, width, and height of the first etch stop region and the second etch stop region are also independent of each other.

The distance between the first field plate structure(s) 210 and the drain vias 198 in the Y-axis (length direction) is indicated here as having the value D. This distance is measured between the closest sides of these two sets of structures. The distance between the first field plate structure(s) 210 and the second field plate structure(s) 230 in the Y-axis (length direction) is indicated here with reference numeral 243. This distance is also measured between the closest sides of the two sets of field plate structures. In some particular embodiments, this value 243 of the distance between the first field plate structure(s) 210 and the second field plate structure(s) 230 may range from about 0.1D to about 0.7D (i.e. about 10% to about 70% of the distance D, or from about 0.1D to about 0.5D, or from about 0.2D to about 0.4D. However, other ranges and values are within the scope of the present disclosure.

FIG. 1D illustrates one potential variation in the plan view. In this variation, the first field plate structure 210 and the second field plate structure 230 have different shapes. Here, the second field plate structure 230 is illustrated as having a trench shape, whereas the first field plate structures 210 are square-shaped. The second field plate structure is indicated as having a width 233, and the second etch stop region is indicated as having a width 173. For purposes of the present disclosure, the field plate structure may be considered to have a trench shape when the width 233 of a given field plate structure is 80% or more of the width 173 of the given etch stop region (when seen from a plan view). As a result, generally there is only one such field plate structure over the etch stop region, rather than multiple field plate structures. This also applies to the first field plate structure 210. A trench shape increases the coverage of the electric field generated by the field plate structure, and may improve I_{DLIN} degradation.

FIG. 1E illustrates a second embodiment of the semiconductor device 100. In this embodiment, the second etch stop region 170 is lower than the first etch stop region 160. Put another way, the height 152 of the first dielectric layer below the first etch stop region is greater than the height 156 below the second etch stop region. This change in the height of the field plate structure 230 proximate the drain electrode 134 modifies the electric field on the drain side of the device, increasing the BV_{off}. In some particular embodiments, the height 156 below the second etch stop region is 0.5X or less. However, other ranges and values are within the scope of the present disclosure. In addition, in FIG. 1A, the second field plate structure 230 is not electrically connected to the source electrode 132. Here, the horizontal pad 196 contacts the source via 194, the first field plate structure 210, and the second field plate structure 230.

FIG. 1F illustrates a third embodiment of the semiconductor device 100. In this illustration, the height of the first dielectric layer below the first etch stop region is indicated with reference numeral 153, and the height of the first dielectric layer below the second etch stop region is indicated with reference numeral 157. Compared to FIG. 1B, the height 153 of the first dielectric layer below the first etch stop region in this embodiment is less than its height 152 in the embodiment of FIG. 1B. This change in the height of the field plate structure 210 proximate the gate electrode 138 modifies the electric field on the gate side of the device, improving HCl performance. In some particular embodiments, the height 153 below the first etch stop region is 0.5X or less. The height 157 of the first dielectric layer below the second etch stop region in this embodiment is the same as its height 156 in the embodiment of FIG. 1B. However, other ranges and values are within the scope of the present disclosure.

FIG. 1G illustrates a fourth embodiment of the semiconductor device 100. Again, the height of the first dielectric layer below the first etch stop region is indicated with reference numeral 153, and the height of the first dielectric layer below the second etch stop region is indicated with reference numeral 157. The height 153 of the first dielectric layer below the first etch stop region in this embodiment is less than its height 152 in the embodiment of FIG. 1B. The height 157 of the first dielectric layer below the second etch stop region in this embodiment is also less than its height 156 in the embodiment of FIG. 1B. In some particular embodiments, both heights 153, 157 are independently 0.5X or less. However, other ranges and values are within the scope of the present disclosure.

FIG. 1H illustrates a fifth embodiment of the semiconductor device 100. In this embodiment, each field plate structure 210, 230 includes a cap 214 at the end of one or more of the via(s) 212, 232. As illustrated here, the cap 214 is made underneath an etch stop region 210, 230. Generally, the cap has a length 215 or diameter which is greater than the length 213 of the bottom of the via. The shape of the cap may vary depending on the number of vias, the shape of the via, etchant, timing, etc., and is illustrated here as a hemispherical shape. As another example, the cap may have a hemicylindrical shape if the via is a trench shape as described above in FIG. 1D. As described in the magnified view of the cap 214, in particular embodiments, the length 215 of the cap may have a value of 2R, and the height 217 of the cap may have a value of about 0.5R to about 1R. The length 213 of the bottom of the via is less than 2R. However, other ranges and values are within the scope of the present disclosure. The use of caps can make the electric field generated by the field plate structures more isotropic. This may increase the BV_{off} and improve I_{DLIN} degradation.

FIG. 1I illustrates a fifth embodiment of the semiconductor device 100. In this embodiment, the gate spacer(s) 140 have a height equivalent to that of the gate electrode 138. In addition, the first dielectric layer 150 does not cover the gate electrode 138 (compare to FIG. 1A). Put another way, the hump portion 151 of FIG. 1A is not present in this embodiment. Also, the horizontal pad 196 electrically connects the source electrode 132 to the second field plate structure 230, not the first field plate structure 210. The first via 212 is electrically connected to second pad 240.

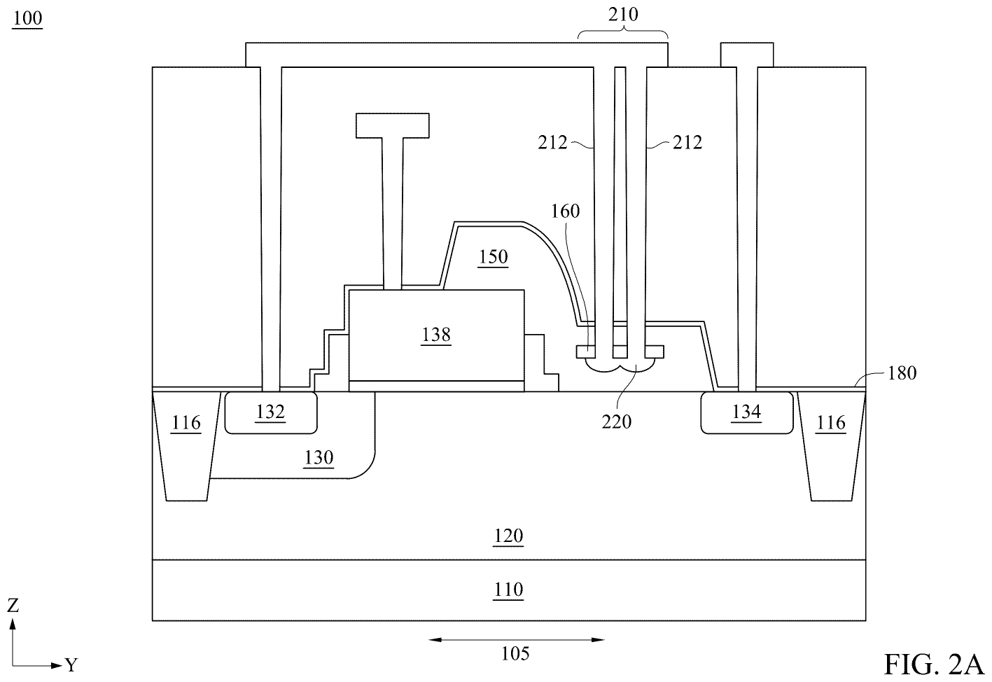

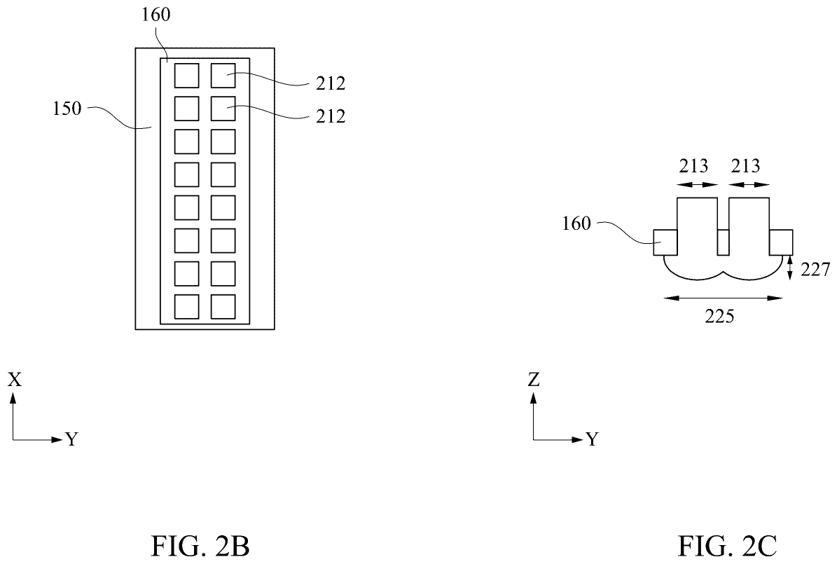

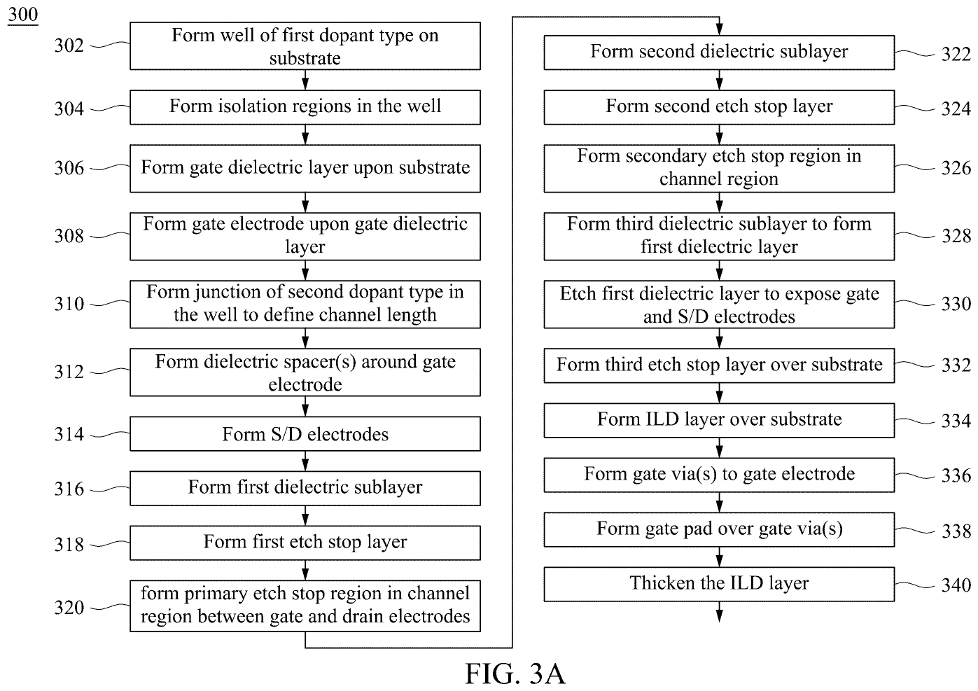

FIGS. 2A-2C are different views of an embodiment of another semiconductor device 100. Whereas the embodiment of FIG. 1A includes two separate etch stop regions in the first dielectric layer 150, in the embodiment of FIG. 2A, only one etch stop region 160 is present. In addition, the field plate structure 210 includes a plurality of vias 212 that pass through the first etch stop region 160 and are formed in the length direction (i.e. first axis 105) from the gate electrode 138 to the drain electrode 134, and also includes a metal field plate 220 underneath the first etch stop region 160. Two such vias 212 are visible in FIG. 2A. The metal field plate can be formed from caps (see FIG. 1H) which are joined together. FIG. 2B is a plan view showing the vias 212 passing through the first etch stop region 160. As seen here, two vias are formed in the length direction (i.e. Y-axis). Eight vias are formed in the width direction (i.e. X-axis). This may increase the BV_{off} and improve I_{DLIN} degradation.

As described in the magnified view of FIG. 2C, in particular embodiments, the length 213 of the bottom of the via has a value of 2R. The length 225 of the metal field plate may range from about 5R to about 6R. The height 227 of the metal field plate may have a value of about 0.5R to about 1R. However, other ranges and values are within the scope of the present disclosure.

For avoidance of doubt, any of the individual variations illustrated in FIGS. 1A-2C may be combined to form a different semiconductor device.

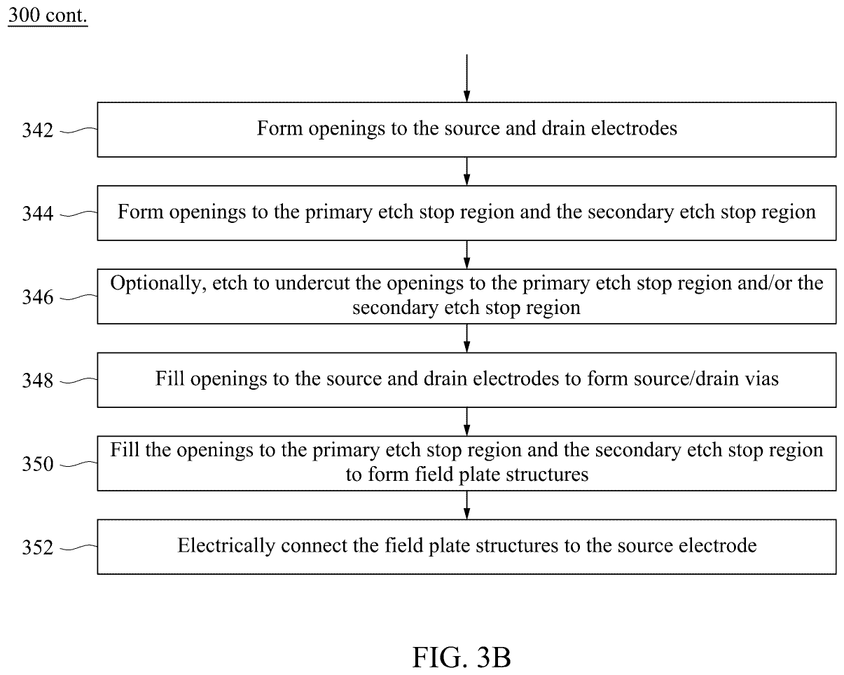

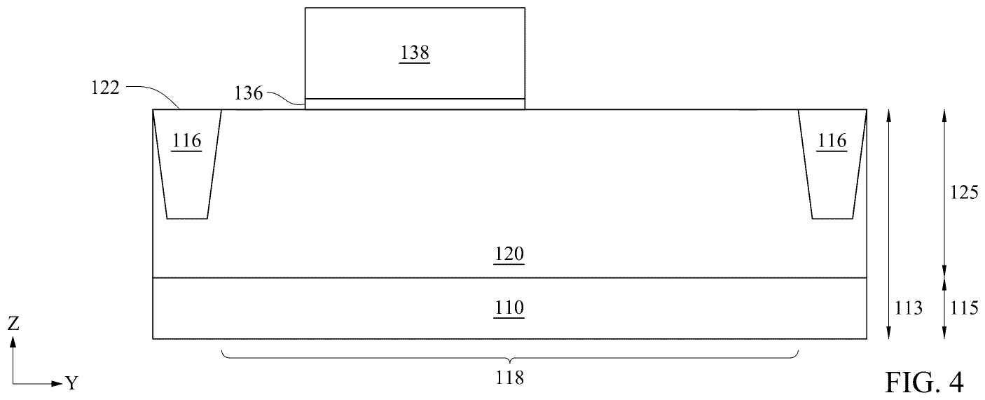

FIG. 3A and FIG. 3B together form a flow chart illustrating a method 300 for forming a semiconductor device, in accordance with some embodiments. Some steps of the method are also illustrated in FIGS. 4-18. These figures provide different views for better understanding. While the method steps are discussed below in terms of forming a single semiconductor device, such discussion should also be broadly construed as applying to the concurrent formation of multiple semiconductor devices. Other structures may also be concurrently formed, and additional layers may also be formed between the various components shown herein. It is noted that not all steps described in the flow chart are required.

Initially, FIG. 4 includes a substrate 110 on which the transistor will be formed. The substrate may be, for example, a wafer made of a semiconducting material. Such semiconductor materials can include silicon, for example in the form of crystalline Si. In alternative embodiments, the substrate can be made of other elementary semiconductors such as germanium, silicon carbide (SiC), silicon germanium, or silicon germanium carbide. The substrate may alternatively include a compound semiconductor such as gallium arsenide (GaAs), gallium phosphide, gallium carbide, indium arsenide (InAs), indium phosphide (InP), gallium arsenic phosphide, gallium indium phosphide, cadmium telluride, or cadmium sulfide. In particular embodiments, the substrate is silicon.

The substrate has an initial height 113. Next, in step 302 of FIG. 3A and referring to FIG. 4, a well 120 of a first dopant type is formed on the substrate. This is typically performed by doping the substrate with the first dopant type. For example, here, the substrate 110 is a p-substrate, and the well 120 will be an n-well.

The doping may be performed by ion implantation or other suitable methods. Briefly, in ion implantation, an ion implanter is used to implant atoms into a silicon crystal lattice, modifying the conductivity of the lattice in the implanted location. An ion implanter generally includes an ion source, a beam line, and a process chamber. The ion source produces the desired ions. The beam line organizes the ions into a beam having high purity in terms of ion mass, energy, and species. A mask, such as a patterned photoresist layer or a hard mask layer, is used to expose desired regions of the substrate. The ion beam is then used to irradiate the semiconducting wafer substrate in a process chamber. The ion beam strikes the exposed regions on the wafer substrate, and the ions can be implanted into the substrate as dopants at desired depths. Alternatively, the substrate can be partially etched, followed by blanket deposition of the dopant, following by annealing in which the dopant reacts with the underlying exposed silicon. As a result, the substrate has a final height 115 and the well 120 has a height 125, which together are about equal to the initial height 113 of the substrate.

Then, in step 304, one or more isolation regions 116 are formed in the substrate 110 to define an active region 118 of the substrate. The isolation regions may be, for example, shallow trench isolation (STI) regions or deep trench isolation (DTI) regions. The isolation regions are formed by patterning the substrate, etching isolation trenches, and filling the trenches with a dielectric material to obtain the isolation regions 116. The dielectric material in the isolation region is commonly silicon dioxide, although other dielectric materials can also be used such as undoped polysilicon, silicon oxide (e.g. SiO2), silicon nitride, silicon oxynitride, fluoride-doped silicate glass, or other low-k dielectric material. The deposition can be done using physical vapor deposition (PVD) or chemical vapor deposition (CVD) or spin-on processes known in the art, or can be grown via oxidation. If desired, the dielectric material can be deposited to a level above that of the well upper surface 122, then recessed back down to the desired height.

Next, in step 306 of FIG. 3A, a gate dielectric layer 136 is formed on the substrate 110. Again, CVD, PVD, atomic layer deposition (ALD), ion implantation, or other suitable deposition process may be used to form the gate dielectric layer. Thermal oxidation may also be used. The gate dielectric layer may be made, for example, from silicon dioxide, silicon oxynitride (SiOₓN_{y}), SiN, HfO, doped HfO, or other high-k dielectric material. The gate dielectric layer 136 is formed in the active region 118 between the isolation regions 116. Afterwards, in step 308, a gate electrode 138 is formed on the gate dielectric layer 136. This may be done by CVD, PVD, or other suitable process. In particular embodiments, the gate precursor layer is made of polysilicon. The resulting structure is shown in FIG. 4.

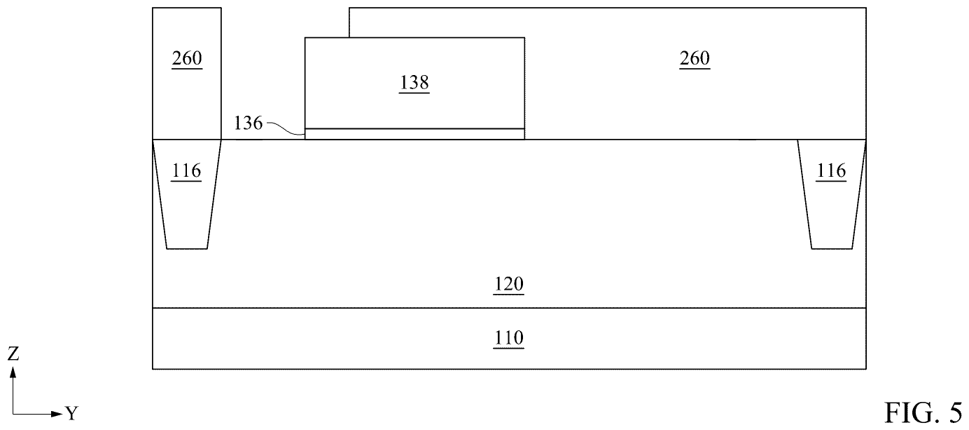

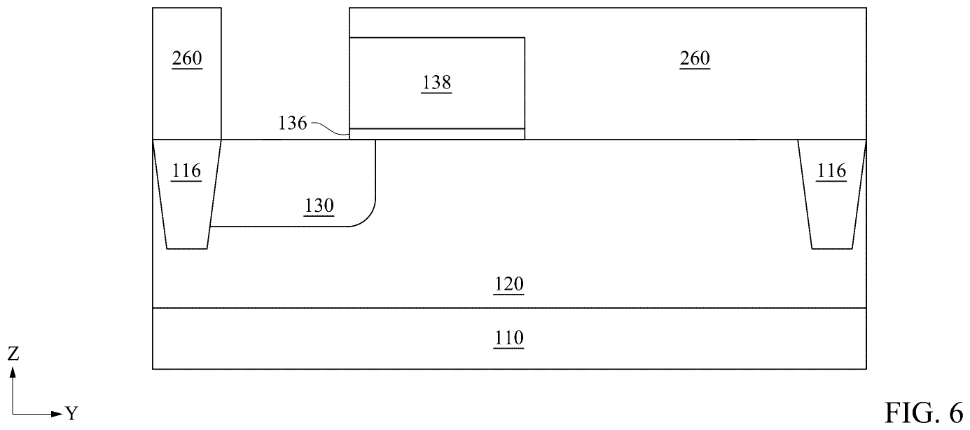

Next, in step 310 of FIG. 3A, a junction 130 of a second dopant type is formed in the well 120 of the first dopant type. The junction aids in controlling the channel length of the semiconductor device. To correct for any process deviations, this may be done in a multi-step process. Referring to FIG. 5, a photoresist layer 260 is applied over the substrate and patterned to expose the location in the well 120 in which the junction is to be formed. As illustrated here, portions of the gate electrode 138 and the gate dielectric layer 136 are exposed. In this regard, in the prior steps, the gate electrode 138 and the gate dielectric layer 136 may have been formed larger than desired in the final product to ensure that their final size was not too small, which would result in less control of the properties of the final product. Then, as illustrated in FIG. 6, the exposed portions of the gate electrode and the gate dielectric layer are etched away. The junction 130 is then formed, for example by ion implantation. It is noted that the junction may extend underneath the gate electrode 138. Here, a p-body junction is formed. The resulting structure is shown in FIG. 6.

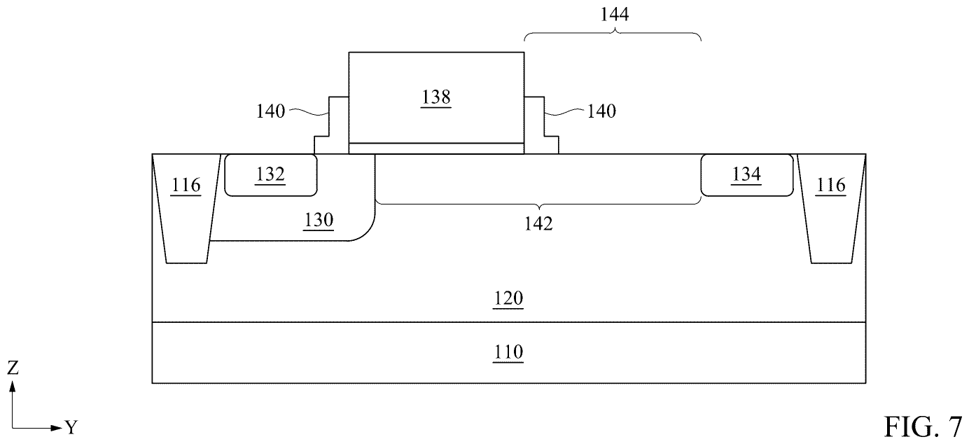

Continuing, in step 312 of FIG. 3A and referring to FIG. 7, at least one gate spacer 140 may be formed on the sidewalls of the gate electrode 138. For example, from a plan view (not shown), one gate spacer may surround the gate electrode on all sides. The gate spacer(s) are vertically oriented, and have a relatively narrow width. The gate spacers can be made from a dielectric material for electrical isolation of the gate electrode. In particular embodiments, the gate spacer(s) are silicon nitride (SiN) or silicon dioxide (SiO₂). The gate spacer(s) can be made by CVD, PVD, ALD, or other deposition technique. Then, in step 314, source/drain (S/D) electrodes 132, 134 are formed in the active region 118. As indicated here, the S/D electrodes 132, 134 are formed on opposite sides of the gate electrode 138. They may be formed using ion implantation or other suitable methods to dope the silicon substrate, or by patterning and deposition of suitable metals. The electrodes are formed from the first dopant type. The resulting structure is shown in FIG. 7. A semiconducting channel 142 is formed between the junction 130 and the drain electrode 134. A channel region 144 is defined between the gate electrode 138 and the drain electrode 134.

As previously mentioned, the first dopant type and the second dopant type have opposite charge. The substrate 110, well 120, junction 130, and S/D electrodes 132, 134 may be reversed in type, depending on whether an NMOS or PMOS is desired.

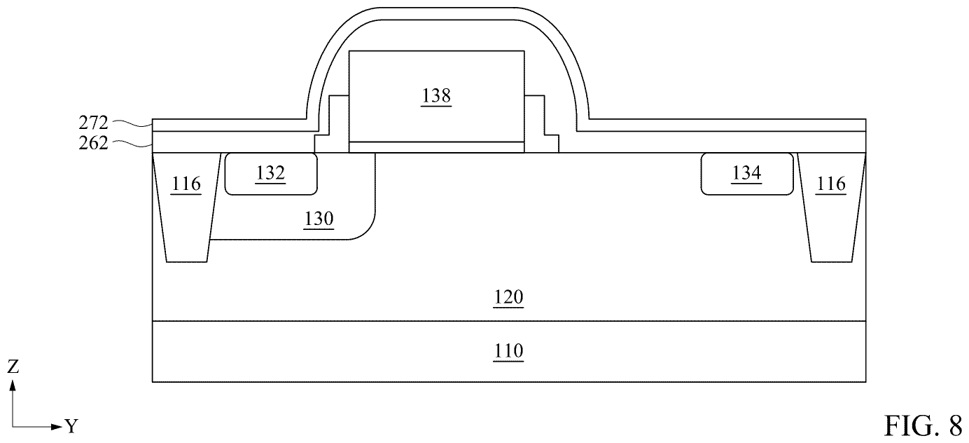

Next, in step 316 of FIG. 3A and referring to FIG. 8, a first dielectric sublayer 262 is formed over the substrate 110. In particular embodiments, this sublayer is a resist protective oxide (RPO) sublayer. The RPO sublayer may be a dielectric material, such as silicon dioxide, silicon oxynitride, or other suitable material. This sublayer may be formed using CVD, PVD, ALD, or other suitable deposition technique. Then, in step 318, a first etch stop layer 272 is formed over the first dielectric sublayer 262. The first etch stop layer is made of a dielectric material that is different from the material of the first dielectric sublayer 262, and may be formed using similar processes. In particular embodiments, the first etch stop layer is made of silicon nitride (SiN). The resulting structure is shown in FIG. 8.

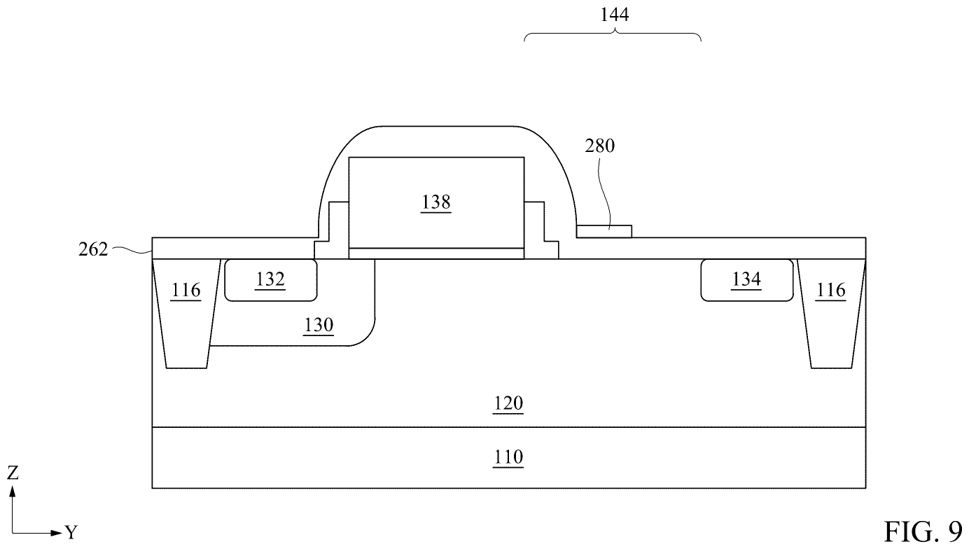

Subsequently, in step 320 of FIG. 3A and referring to FIG. 9, the first etch stop layer 272 is patterned and etched to form a first etch stop region 280 in the channel region 144. The first etch stop region may correspond to the first etch stop region 160 or the second etch stop region 170 of FIGS. 1A-1I, whichever is deeper in the first dielectric layer. As illustrated here, the first etch stop region 280 will correspond to the first etch stop region 160.

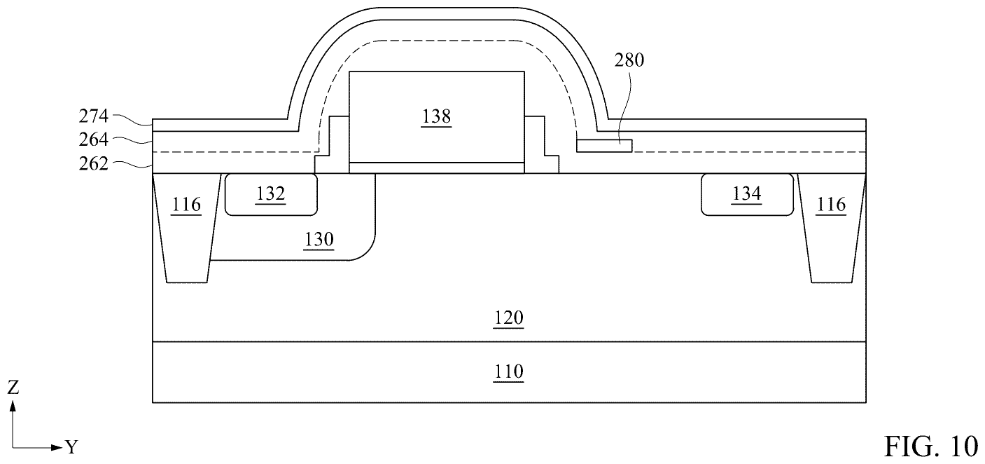

Next, in step 322 of FIG. 3A and referring to FIG. 10, a second dielectric sublayer 264 is formed over the substrate 110. This sublayer is made of the same material as the first dielectric sublayer 262. This sublayer also covers the first etch stop region 280. Then, in step 324, a second etch stop layer 274 is formed over the second dielectric sublayer 264. The second etch stop layer is made of a dielectric material that is different from the material of the second dielectric sublayer 264, and may be the same material as that of the first etch stop layer 272/first etch stop region 280. The resulting structure is shown in FIG. 10.

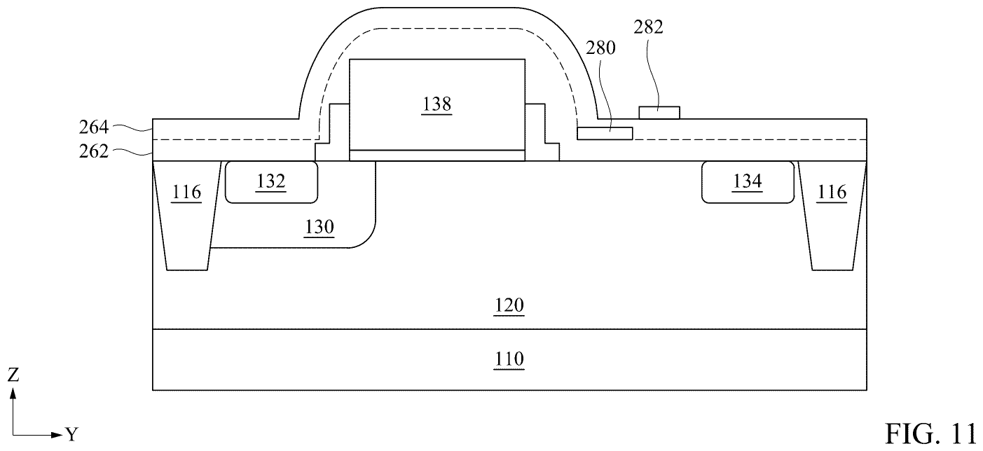

Continuing, in step 326 of FIG. 3A and referring to FIG. 11, the second etch stop layer 274 is patterned and etched to form a second etch stop region 282 in the channel region 144. The second etch stop region 282 is offset along the channel length from the first etch stop region 280, or put another way does not overlap the first etch stop region. The second etch stop region may correspond to the second etch stop region 170 or the second etch stop region 170 of FIGS. 1A-1I, whichever is shallower in the first dielectric layer. As illustrated here, the second etch stop region 282 will correspond to the second etch stop region 170.

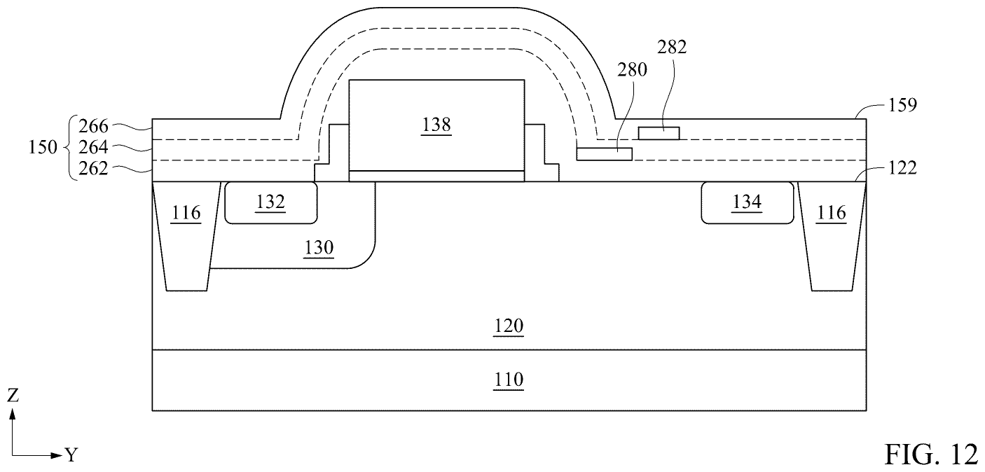

Then, in step 328 of FIG. 3A and referring to FIG. 12, a third dielectric sublayer 266 is formed over the substrate 110. This sublayer is made of the same material as the first dielectric sublayer 262 and the second dielectric sublayer 264. This sublayer also covers both the first etch stop region 280 and the second etch stop region 282. Together the three sublayers 262, 264, 266 form the first dielectric layer 150 of FIG. 1A. The first etch stop region 280 and the second etch stop region 282 may be described as being at different heights relative to the upper surface 122 of the well 120, or at different depths relative to the upper surface 159 of the first dielectric layer 150.

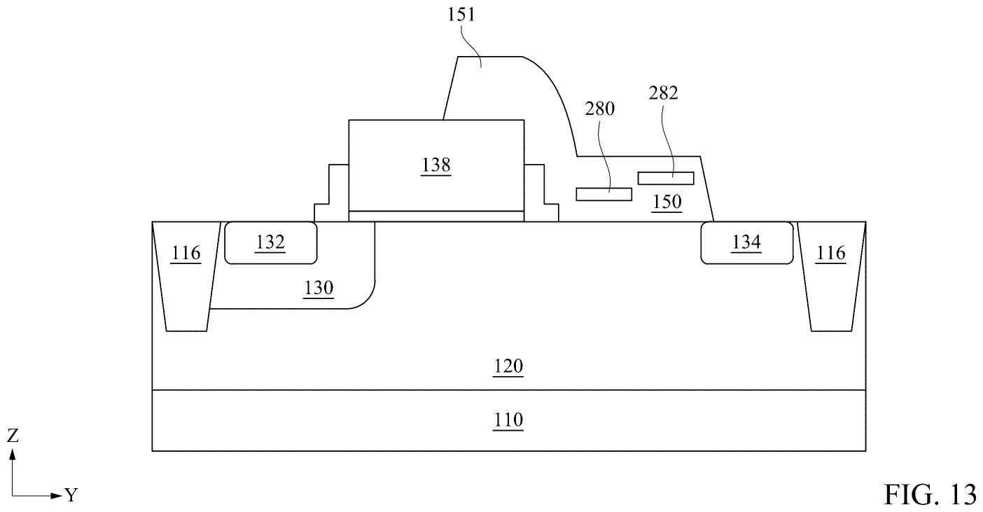

In step 330 of FIG. 3A and referring to FIG. 13, the first dielectric layer 150 is etched to expose the gate electrode 138 and the S/D electrodes 132, 134 from above. A hump portion 151 of the first dielectric layer 150 covers a portion of the gate electrode 138

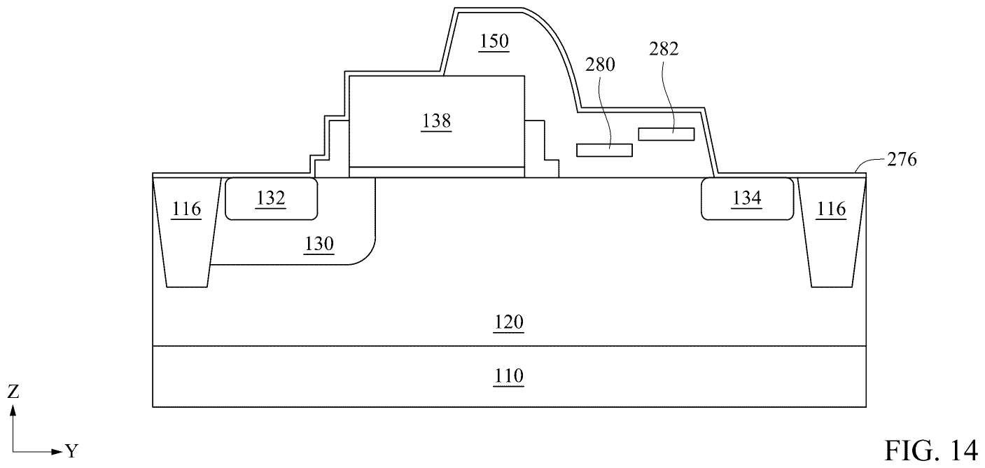

Next, in step 332 of FIG. 3A and referring to FIG. 14, a third etch stop layer 276 is formed over the substrate and over the first dielectric layer 150. The third etch stop layer 276 corresponds to the etch stop layer 180 of FIG. 1A. The third etch stop layer covers the S/D electrodes 132, 134, the gate spacer(s) 140, the gate electrode 138, the first dielectric layer 150, and may also cover the isolation regions 116. The third etch stop layer is made of a dielectric material that is different from the material of the first dielectric layer 150. The dielectric material may be the same material as that of the first etch stop layer 272/first etch stop region 280 and/or the second etch stop layer 274/second etch stop region 282.

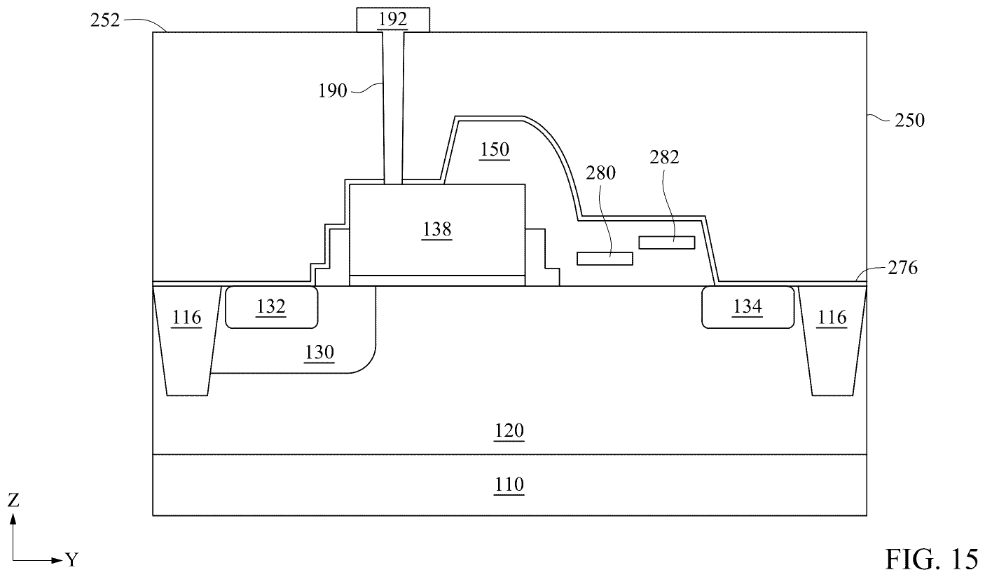

Next, in step 334 of FIG. 3A and referring to FIG. 15, an interlayer dielectric (ILD) layer 250 is formed over the substrate. The ILD layer is made of a dielectric material that is different from the material of the third etch stop layer 276. The dielectric material may be the same material as that of the first dielectric layer 150. Then, in step 336, one or more gate vias 190 are formed to the gate electrode 138. In step 338, a gate pad 192 is formed on the upper surface 252 of the ILD layer 250 over the gate via(s) 190.

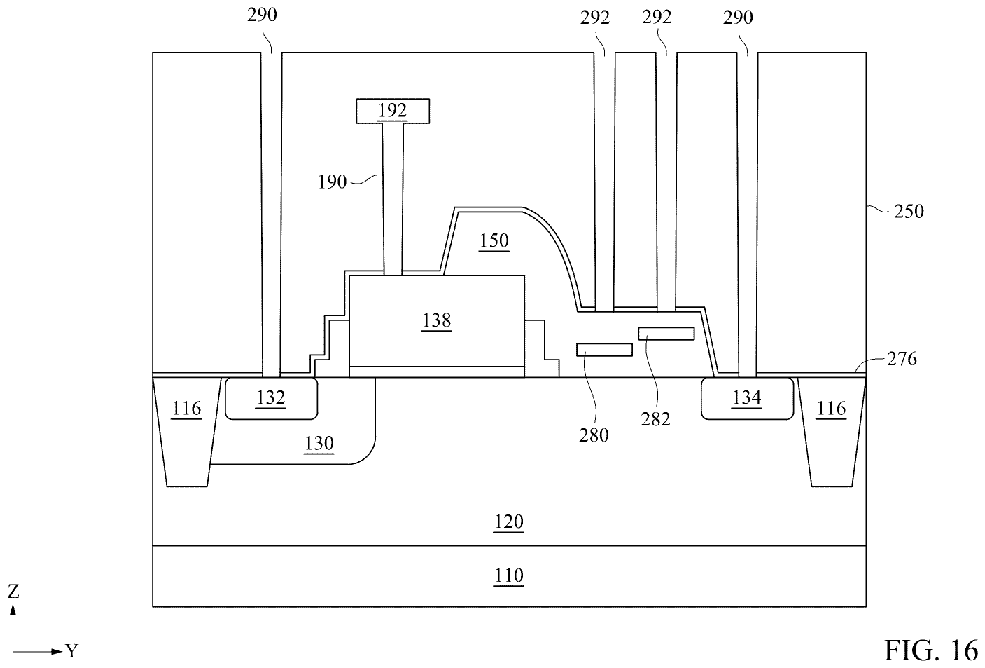

Next, in step 340 of FIG. 3A and referring to FIG. 16, the thickness of the ILD layer 250 is increased by deposition of additional dielectric material to cover the gate pad 192. Then, in step 342 of FIG. 3B, openings 290 to the S/D electrodes are formed. In step 344 of FIG. 3B, openings 292 to the first etch stop region 280 and the second etch stop region 282 are formed. These two steps may be performed concurrently in overlapping steps of a multi-step process.

As illustrated in FIG. 16, first, the ILD layer 250 is etched in desired locations using an etchant. Next, the exposed third etch stop layer 276 is etched using a different etchant from the prior etch step. The S/D electrodes 132, 134 are thus exposed. The first dielectric layer 150 is also exposed.

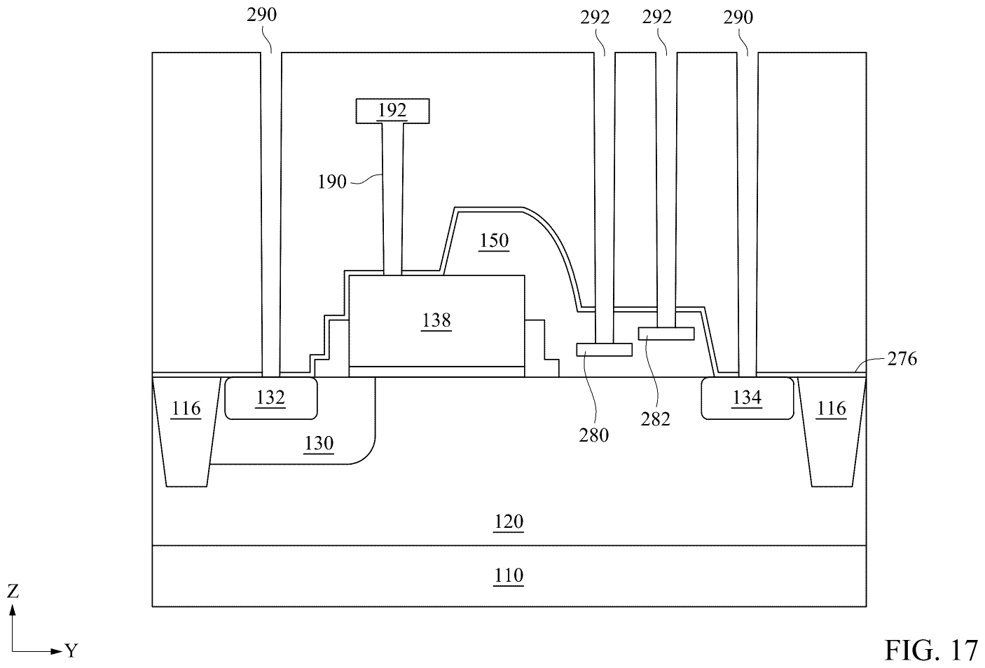

Continuing, in FIG. 17, the exposed first dielectric layer 150 is etched down to the first etch stop region 280 and the second etch stop region 282, again using a different etchant from the prior etch step.

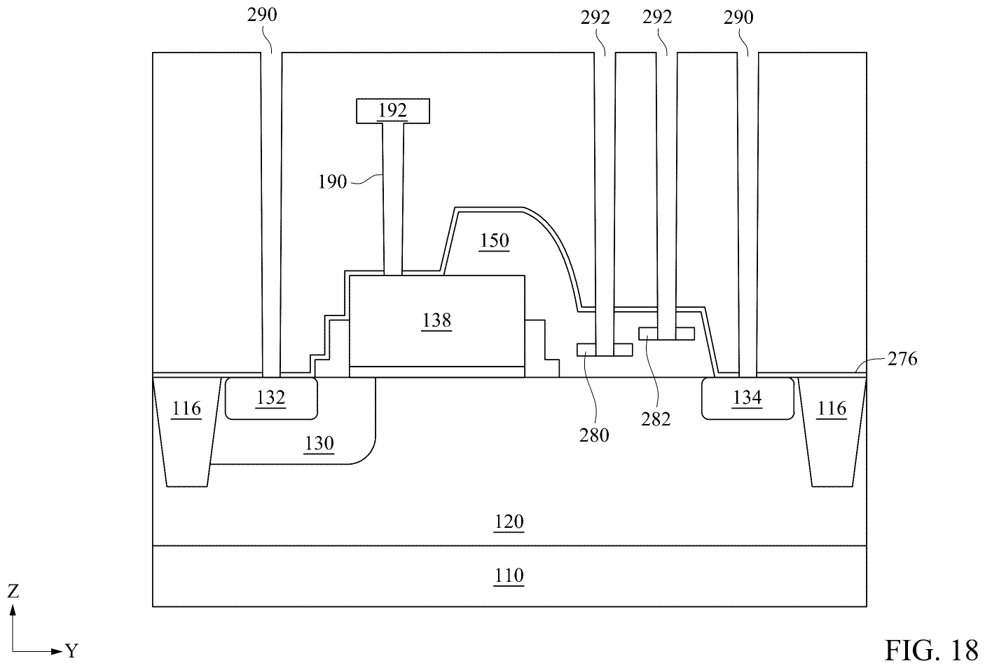

Then, in FIG. 18, the first etch stop region 280 and the second etch stop region 282 are etched, again using a different etchant from the prior etch step, to reach the portion of the first dielectric layer 150 underneath the first etch stop region 280 and the second etch stop region 282. In optional step 346 (not illustrated), the portion of the first dielectric layer 150 underneath the first etch stop region 280 and the second etch stop region 282 may be etched, again using a different etchant from the prior etch step. Typically, this optional step may be performed using a liner removal process, or by wet etching to undercut the etch stop region. This multi-step process provides more control over the depth of the resulting field plate structures.

Next, in step 348 of FIG. 3B and referring to both FIG. 18 and FIG. 1A, the openings 290 to the S/D electrodes are filled with an electrically conductive material to form source/drain vias 194, 198. In step 350, the openings 292 to the first etch stop region 280 and the second etch stop region 282 are filled with an electrically conductive material to form at least one first field plate structure 210 and at least one second field plate structure 230. These steps may be performed concurrently. In step 352, a horizontal pad 196 is formed on the upper surface 252 of the ILD layer 250 that electrically connects at least one first field plate structure 210 or second field plate structure 230 to the source electrode 132. The resulting structure is shown in FIG. 1A.

While FIG. 1A and the method of FIG. 3A and FIG. 3B illustrate two field plate structures 210, 230 arranged along the Y-axis between the gate electrode 138 and the drain electrode 134, the present disclosure also contemplates that more field plate structures could be present. Depending on the dimensions of the semiconductor device, as many as eight (8) field plate structures could be present. This can be done by creating more than two etch stop regions in a given etch stop layer, or increasing the number of dielectric sublayers and etch stop layers which are deposited and patterned. In addition, while FIG. 1A illustrates a planar transistor, the methods can also be applied to three-dimensional transistors such as FinFETs.

The structures and methods of the present disclosure discussed above refer to dielectric layers. Such dielectric layers can generally be made from any suitable dielectric material or combination thereof, although the characteristics of any particular layer may also be further defined. Examples of dielectric materials may include silicon dioxide (SiO₂), silicon nitride (Si₃N₄), silicon carbide (SiC), hafnium dioxide (HfO₂), zirconium dioxide (ZrO₂), aluminum oxide (Al₂O₃), silicon oxynitride (SiOₓN_{y}), hafnium oxynitride (HfOₓN_{y}) or zirconium oxynitride (ZrOₓN_{y}), or hafnium silicates (HfSiₓO_{y}) or zirconium silicates (ZrSiₓO_{y}) or silicon carboxynitride (SiCₓO_{y}N_{z}), or hexagonal boron nitride (hBN). Other dielectric materials may include tantalum oxide (Ta₂O₅), nitrides such as silicon nitride, polysilicon, phosphosilicate glass (PSG), fluorosilicate glass (FSG), undoped silicate glass (USG), high-stress undoped silicate glass (HSUSG), and borosilicate glass (BSG). They may be low-k dielectrics, extremely low-k dielectrics, or high-k dielectrics. The dielectric layer may be formed by any suitable means, including chemical vapor deposition (CVD), physical vapor deposition (PVD), atomic layer deposition (ALD), thermal oxidation, or other suitable methods.

Any electrically conductive material discussed herein may generally be any conductive metal or conductive oxide. Examples of suitable metals may include copper, aluminum, nickel, chromium, gold, germanium, silver, titanium, tungsten, platinum, tantalum, ruthenium, cobalt, rhenium, palladium, or zirconium; composites like TiN, WN, or TaN; or alloys thereof like AlCu. Examples of suitable conductive oxides may include indium tin oxide (ITO), zinc oxide (ZnO), tin oxide (SnO), aluminum zinc oxide (AlZnO), indium oxide (InO), or cadmium oxide (CdO). The metal or oxide material may be deposited, for example, via evaporation or sputtering, plating, chemical vapor deposition (CVD), physical vapor deposition (PVD), atomic layer deposition (ALD), or other suitable methods.

It is also noted that certain conventional steps are not expressly described in the discussion above. For example, a pattern / structure may be formed in a given layer by applying a photoresist layer, patterning the photoresist layer, developing the photoresist layer to form a mask, and then etching through the mask to transfer the pattern to the given layer.

Generally, a photoresist layer may be applied, for example, by spin coating, or by spraying, roller coating, dip coating, or extrusion coating. Typically, in spin coating, the substrate is placed on a rotating platen, which may include a vacuum chuck that holds the substrate in plate. The photoresist composition is then applied to the center of the substrate. The speed of the rotating platen is then increased to spread the photoresist evenly from the center of the substrate to the perimeter of the substrate. The rotating speed of the platen is then fixed, which can control the thickness of the final photoresist layer.

Next, the photoresist composition is baked or cured to remove the solvent and harden the photoresist layer. In some particular embodiments, the baking occurs at a temperature of about 90° C. to about 110° C. The baking can be performed using a hot plate or oven, or similar equipment. As a result, the photoresist layer is formed on the substrate.

The photoresist layer is then patterned via exposure to radiation. The radiation may be any light wavelength which carries a desired mask pattern. In particular embodiments, EUV light having a wavelength of about 13.5 nm is used for patterning, as this permits smaller feature sizes to be obtained. This results in some portions of the photoresist layer being exposed to radiation, and some portions of the photoresist not being exposed to radiation. This exposure causes some portions of the photoresist to become soluble in the developer and other portions of the photoresist to remain insoluble in the developer.

An additional photoresist bake step (post exposure bake, or PEB) may occur after the exposure to radiation. For example, this may help in releasing acid leaving groups (ALGs) or other molecules that are significant in chemical amplification photoresist.

The photoresist layer is then developed using a developer. The developer may be an aqueous solution or an organic solution. The soluble portions of the photoresist layer are dissolved and washed away during the development step, leaving behind a photoresist pattern (i.e. a mask). One example of a common developer is aqueous tetramethylammonium hydroxide (TMAH). Generally, any suitable developer may be used. Sometimes, a post develop bake or “hard bake” may be performed to stabilize the photoresist pattern after development, for optimum performance in subsequent steps.

Continuing, portions of the given layer below the patterned photoresist mask are now exposed. Etching transfers the photoresist pattern to the given layer below the patterned photoresist mask. After use, the mask can be removed, for example, using various solvents such as N-methyl-pyrrolidone (NMP) or alkaline media or other strippers at elevated temperatures, or by dry etching using oxygen plasma.

Generally, any etching step described herein may be performed using wet etching, dry etching, or plasma etching processes such as reactive ion etching (RIE) or inductively coupled plasma (ICP), or combinations thereof, as appropriate. The etching may be anisotropic. Depending on the material, etchants may include carbon tetrafluoride (CF₄), hexafluoroethane (C₂F₆), octafluoropropane (C₃F₈), fluoroform (CHF₃), difluoromethane (CH₂F₂), fluoromethane (CH₃F), carbon fluorides, nitrogen (N₂), hydrogen (H₂), oxygen (O₂), argon (Ar), xenon (Xe), xenon difluoride (XeF₂), helium (He), carbon monoxide (CO), carbon dioxide (CO₂), fluorine (F₂), chlorine (Cl₂), hydrogen bromide (HBr), hydrofluoric acid (HF), nitrogen trifluoride (NF₃), sulfur hexafluoride (SF₆), boron trichloride (BCl₃), ammonia (NH₃), bromine (Br₂), or the like, or combinations thereof in various ratios. For example, silicon dioxide can be wet etched using hydrofluoric acid and ammonium fluoride. Alternatively, silicon dioxide can be dry etched using various mixtures of CHF₃, O₂, CF₄, and/or H₂.

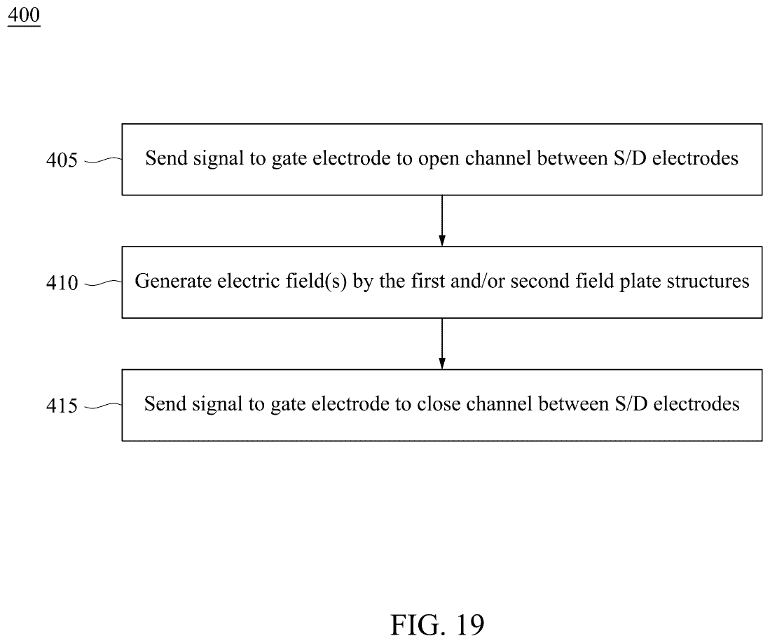

FIG. 19 is a flow chart illustrating a method 400 for using a semiconductor device, in accordance with some embodiments. The method steps are discussed below in terms of using a single semiconductor device, and should also be broadly construed as applying to the concurrent use of multiple semiconductor devices. Reference is also made to the structure of FIG. 1A.

In step 405 of FIG. 19, a signal is sent to the gate electrode 138. Typically, a voltage signal is sent, either in the form of an increased voltage or a decreased voltage (depending on how the gate electrode is operated). This opens a channel 142 between the source electrode 132 and the drain electrode 134, which permits current to flow from the source electrode to the drain electrode. In step 410, one or more electric fields are generated by the first field plate structure 210 and/or the second field plate structure 230. The shape and strength of such electric fields may be varied based on the location and/or shape of the field plate structures, or by sending different signals to the field plate structures. It is noted that such electric fields may be generated continuously, and are not related to the signal being sent to the gate electrode. In step 415, the channel is closed by changing the signal to the gate electrode, for example by reverting to the prior signal.

The semiconductor devices of the present disclosure may be incorporated into larger semiconductor packages and into larger devices. Such packages may also include various interconnect structures for communicating with other semiconductor devices. The semiconductor devices may be useful in power management devices that control the flow and direction of electrical power. One specific example of such a power management device is a buck converter, which is a DC-to-DC converter that decreases voltage while increasing current. A buck converter usually contains at least two semiconductor devices and at least one energy storage device (e.g. a capacitor or an inductor). Buck converters are useful in computers and mobile devices such as cellphones, tablets, or wearable electronic devices. The semiconductor devices could also be used in other devices such as BCD (Bipolar-CMOS-DMOS) circuits for driving discrete high voltage components; image signal processors (ISP); LCD, OLED, AMOLED, or QLED display panels; image sensors that can be used in systems such as mobile telephones, facial recognition systems, or as motion sensors for automotive applications, security applications, energy efficiency, etc.

The semiconductor devices and methods of the present disclosure have several advantages. They have improved performance in properties like I_{DLIN}, BV_{off}, and HCl. The methods provide increased horizontal control and vertical control in the placement of the field plate structures, permitting increased tuning in the manufacturing process.

Some embodiments of the present disclosure thus relate to methods for forming a semiconductor device. A gate electrode, a source electrode, and a drain electrode are formed on a semiconducting substrate. At least a first etch stop region is formed in a channel region between the gate electrode and the drain electrode and within a first dielectric layer. An etch stop layer is formed over the substrate. At least one via is formed through the first etch stop region to obtain at least one first field plate structure. The at least one first field plate structure is then electrically connected to the source electrode.

In some embodiments, a first etch stop region and a second etch stop region are formed in the channel region. The two etch stop regions are located at different heights within the first dielectric layer.

In other embodiments, a plurality of first field plate structures are formed along a first axis from the gate electrode to the drain electrode and joined together by a metal field plate below the first etch stop region.

Other embodiments disclosed herein relate to semiconductor devices that comprise a gate electrode, a source electrode, and a drain electrode on a semiconducting substrate. At least a first etch stop region and a second etch stop region are located in a channel region between the gate electrode and the drain electrode and within a first dielectric layer on the semiconducting substrate. At least one first field plate structure contacts the first etch stop region. At least one second field plate structure contacts the second etch stop region. The at least one first field plate structure and the at least one second field plate structure are at different heights within the first dielectric layer. An electrical connection extends from the at least one first field plate structure or the at least one second field plate structure to the source electrode.

The present disclosure also relates in various embodiments to methods for using a semiconductor device having at least one first field plate structure and at least one second field plate structure located at different heights/depths within the first dielectric layer. A signal to the gate electrode opens a channel between the source electrode and the drain electrode. Electric fields generated by the two field plate structures modify the properties of the device. The channel is then closed by sending a different signal to the gate electrode.

Also described in various embodiments herein are devices that include a semiconductor device having at least one first field plate structure and at least one second field plate structure located at different heights/depths within the first dielectric layer.

Other embodiments disclosed herein relate to semiconductor devices comprising a gate electrode, a source electrode, and a drain electrode on a semiconducting substrate. A first etch stop region is located in a channel region between the gate electrode and the drain electrode and within a first dielectric layer on the semiconducting substrate. A plurality of vias extend through the first etch stop region to form at least one first field plate structure. The plurality of vias are located along a first axis from the gate electrode to the drain electrode. An electrical connection extends from the plurality of vias to the source electrode. In some more specific embodiments, the plurality of vias are connected to each other by a metal plate below the first etch stop region.

The present disclosure also relates in various embodiments to methods for using a semiconductor device having at least one first field plate structure formed by a plurality of vias located along a first axis from the gate electrode to the drain electrode. A signal to the gate electrode opens a channel between the source electrode and the drain electrode. The electric field generated by the field plate structure modifies the properties of the device. The channel is then closed by sending a different signal to the gate electrode.

Also described in various embodiments herein are devices that include a semiconductor device having at least one first field plate structure formed by a plurality of vias located along a first axis from the gate electrode to the drain electrode.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method for forming a semiconductor device, comprising:
forming a gate electrode, a source electrode, and a drain electrode on a substrate;
forming at least a first etch stop region in a channel region between the gate electrode and the drain electrode and within a first dielectric layer;
forming an etch stop layer over the substrate;
forming at least one via through the first etch stop region to obtain at least one first field plate structure;
electrically connecting the at least one first field plate structure to the source electrode.

2. The method of claim 1, wherein the at least one first field plate structure is formed by:
etching an opening through the etch stop layer;
etching through the first dielectric layer to the first etch stop region to extend the opening;
etching through the first etch stop region to extend the opening; and
filling the opening with an electrically conductive material to form the first field plate structure.

3. The method of claim 2, further comprising:
undercutting the first etch stop region to form a cap at a bottom end of the opening prior to filling the opening.

4. The method of claim 1, wherein the at least one via through the first etch stop region has a trench shape when seen from a plan view.

5. The method of claim 1, wherein a plurality of first field plate structures are formed along a first axis from the gate electrode to the drain electrode and joined together by a metal field plate below the first etch stop region.

6. The method of claim 1, further comprising:
forming a second etch stop region in the channel region prior to forming the etch stop layer over the substrate;
forming at least one via through the second etch stop region to obtain at least one second field plate structure; and
electrically connecting the at least one second field plate structure to the source electrode.

7. The method of claim 6, wherein the first etch stop region and the second etch stop region are located at different heights within the first dielectric layer.

8. The method of claim 7, wherein the first etch stop region and the second etch stop region are formed by:
forming a first dielectric sublayer over the channel region;
forming the first etch stop region on the first dielectric sublayer;
forming a second dielectric sublayer over the channel region;
forming the second etch stop region on the second dielectric sublayer; and
forming a third dielectric sublayer over the channel region to obtain the first dielectric layer.

9. The method of claim 6, wherein the at least one via through the first etch stop region and the at least one via through the second etch stop region have different shapes when seen from a plan view.

10. The method of claim 6, wherein the first etch stop region is closer to the gate electrode than the second etch stop region.

11. The method of claim 10, wherein a distance from the at least one first field plate structure and the at least one second field plate structure is from about 10% to about 70% of a distance from the at least one first field plate structure and a via to the drain electrode.

12. The method of claim 1, further comprising forming a well to define a channel length of the channel region prior to forming the source electrode.

13. The method of claim 1, further comprising forming at least one gate spacer around the gate electrode prior to forming the first etch stop region.

14. The method of claim 1, wherein the first etch stop region has a thickness that is about 10% to about 30% of a thickness of the first dielectric layer.

15. The method of claim 1, further comprising forming at least one interlayer dielectric (ILD) layer over the substrate.

16. A semiconductor device, comprising:
a gate electrode, a source electrode, and a drain electrode on a substrate;
at least a first etch stop region and a second etch stop region in a channel region between the gate electrode and the drain electrode and within a first dielectric layer on the substrate;
at least one first field plate structure contacting the first etch stop region;
at least one second field plate structure contacting the second etch stop region, wherein the at least one first field plate structure and the at least one second field plate structure are at different depths within the first dielectric layer; and
an electrical connection from the at least one first field plate structure or the at least one second field plate structure to the source electrode.

17. The device of claim 16, wherein the first etch stop region is closer to the gate electrode than the second etch stop region.

18. The device of claim 16, wherein the first etch stop region is deeper than the second etch stop region; or
wherein the second etch stop region is deeper than the first etch stop region.

19. A semiconductor device, comprising:
a gate electrode, a source electrode, and a drain electrode on a substrate;
a first etch stop region in a channel region between the gate electrode and the drain electrode and within a first dielectric layer on the substrate;
a plurality of vias extending through the first etch stop region to form at least one first field plate structure, the plurality of vias being located along a first axis from the gate electrode to the drain electrode; and
an electrical connection from the plurality of vias to the source electrode.

20. The semiconductor device of claim 19, wherein the plurality of vias are connected to each other below the first etch stop region.
